(19) United States
(12) Patent Application Publication
(10) Pub. No.: US 2014/0048315 A1
(43) Pub. Date: Feb. 20, 2014

(54) TOUCH PANEL

(71) Applicant: SAMSUNG ELECTRO-MECHANICS CO., LTD., Suwon (KR)

(72) Inventors: Kyoung Soo Chae, Suwon (KR); Yun Ki Hong, Suwon (KR); Sang Hwan Oh, Suwon (KR); Jang Ho Park, Suwon (KR); Seung Joo Shin, Suwon (KR); Ho Joon Park, Suwon (KR)

(73) Assignee: SAMSUNG ELECTRO-MECHANICS CO., LTD., Suwon (KR)

(21) Appl. No.: 13/737,165

(22) Filed: Jan. 9, 2013

(30) Foreign Application Priority Data
Aug. 16, 2012 (KR) 10-2012-0089487

(51) Int. Cl. H05K 1/02

(52) U.S. Cl. CPC H05K 1/02
USPC 174/255

(57) ABSTRACT

Disclosed herein is a touch panel including: a transparent substrate; conductive patterns formed on the transparent substrate such that wavy lines thereof are spaced apart from each other and arranged in parallel with each other, each of the wavy lines having a sine wave form where first peaks and second peaks alternately continue along a length direction thereof; and connecting patterns formed on the transparent substrate, each of the connecting patterns electrically connecting between the wave lines, so that good visibility can be achieved even though electrodes and wirings are disposed in an active area of the transparent substrate, by forming uniform pattern of electrodes and wirings on the transparent substrate.

### CROSS REFERENCE TO RELATED APPLICATION

This application claims the benefit of Korean Patent Application No. 10-2012-0089487, filed on Aug. 16, 2012, entitled “Touch Panel”, which is hereby incorporated by reference in its entirety into this application.

### BACKGROUND OF THE INVENTION

1. Technical Field

The present invention relates to a touch panel.

2. Description of the Related Art

With the development of computers using a digital technology, devices assisting computers have also been developed, and personal computers, portable transmitters and other personal information processors execute text and graphic processing using a variety of input devices such as a keyboard and a mouse.

While the rapid advancement of an information-oriented society has been widening the use of computers more and more, it is difficult to efficiently operate products using only a keyboard and mouse currently serving as an input device. Therefore, the need for a device that is simple, has minimum malfunction, and is capable of easily inputting information has increased.

In addition, current techniques for input devices have progressed toward techniques related to high reliability, durability, innovation, designing and processing beyond the level of satisfying general functions. To attain these objects, a touch panel has been developed as an input device capable of inputting information such as text, graphics, or the like.

The touch panel is mounted on the display surface of an image display device such as an electronic organizer, a flat panel display including a liquid crystal display (LCD), a plasma display panel (PDP), an electroluminescence (El) element or the like, or a cathode ray tube (CRT), so that a user selects the desired information while viewing the image display device.

The touch panel is classified into a resistive type touch panel, a capacitive type touch panel, an electromagnetic type touch panel, a surface acoustic wave (SAW) type touch panel, and an infrared type touch panel. These various types of touch panels are adapted for electronic products in consideration of signal amplification problems, resolution difference, level of difficulty of designing and processing technologies, optical characteristics, electrical characteristics, mechanical characteristics, environment-resistant characteristics, input characteristics, durability, and economic efficiency. Currently, a capacitive type touch panel and a digital resistive type touch panel have been used in a wide range of fields.

An example of the capacitive type touch panel of the prior art is a touch panel disclosed in Korean Patent Laid-Open Publication No. 10-2011-0120157. In the touch panel disclosed in the published patent, a plurality of electrodes having a biaxial direction and crossing each other are formed on a transparent substrate.

In addition, wirings are formed such that each of the wirings is electrically connected with one end of each of the electrodes. A flexible printed circuit board (FPCB) is electrically connected to a pad part formed at terminals of the wirings.

In the touch panel of the prior art having this structure, the foregoing electrodes are disposed in an active area of the transparent substrate, which is exposed to the outside through the transparent substrate or a window glass, and the foregoing wirings are disposed in a non-active area of the transparent substrate, which is not exposed to the outside.

The reason why the wirings are disposed in the non-active area is that the wirings have a line shape generally and thus have uniformity with patterns of the foregoing electrodes disposed in the active area of the transparent substrate.

That is, in the case where the foregoing electrodes are formed in a mesh pattern, the patterns of the linear wirings is uniform with the patterns of the electrodes. Therefore, in the case where the electrodes and the wirings are formed together in the active area, visibility of the touch panel may be defective.

Due to this, the touch panel of the prior art has wirings disposed in the non-active area of the transparent substrate, like the touch panel disclosed in the foregoing published patent.

The touch panel of the prior art has a disadvantage in that, as described above, since the wirings are disposed in the non-active area of the transparent substrate, the width of the non-active area of the touch panel is increased.

This disadvantage may be an obstacle in miniaturizing terminals employing a touch panel structure, or may lead to a limitation that the active area of the transparent substrate, which is a touch area of the same sized device, needs to be reduced.

### SUMMARY OF THE INVENTION

The present invention has been made in an effort to provide a touch panel capable of reducing the width of a non-active area of a transparent substrate thereof, by disposing wirings and electrodes together in an active area of the transparent substrate.

Further, the present invention has been made in an effort to provide a touch panel capable of improving visibility thereof, by forming uniform pattern of electrodes and wirings on a transparent substrate.

According to one preferred embodiment of the present invention, there is provided a touch panel, including: a transparent substrate; conductive patterns formed on the transparent substrate such that wavy lines thereof are spaced apart from each other and arranged in parallel with each other, each of the wavy lines having a sine wave form where first peaks and second peaks alternately continue along a length direction thereof; and connecting patterns formed on the transparent substrate, each of the connecting patterns electrically connecting between the wave lines.

Here, in the conductive patterns, the first peaks of any one of neighboring wavy lines and the second peaks of the other of the neighboring wavy lines may face each other while a distance between the neighboring wavy lines has the shortest interval.

The connecting pattern may be formed in a line shape, both ends of the connecting pattern being connected to the first peak of any one of the neighboring wavy lines and the second peak of the other of the neighboring wavy lines.

Here, in the wavy lines constituting the conductive patterns, any one line may be a wiring and the other lines may be electrodes.

The wavy lines may be arranged at an equal interval on the transparent substrate.

The transparent substrate may be divided into an active area and a non-active area, and the conductive patterns and the connecting patterns may be formed in the active area.

The conductive patterns and the connecting patterns may be integrally formed of the same material.

According to another preferred embodiment of the present invention, there is provided a touch panel, including: a transparent substrate; conductive patterns formed on the transparent substrate such that wavy lines thereof are spaced apart from each other and disposed in parallel with each other, each of the wavy lines having a sine wave form where first peaks and second peaks alternately continue along a length direction thereof; and the conductive patterns being divided into a first conductive part and a second conductive part by forming a cut portion in the wavy lines; and connecting patterns formed on the transparent substrate, each of the connecting patterns electrically connecting between the wave lines.

Here, in the conductive patterns, the first peaks of any one of neighboring wavy lines and the second peaks of the other of the neighboring wave lines may face each other while a distance between the neighboring wavy lines has the shortest interval.

The connecting pattern may be formed in a line shape, both ends of the connecting pattern being connected to the first peaks of any one of neighboring wavy lines and the second peaks of the other of the neighboring wavy lines.

The cutting portion may be formed in the wavy lines along a direction orthogonal to the length direction of the wavy lines.

Here, in the wavy lines constituting the first conductive part, any one line may be a first wiring and the other lines may be first electrodes.

Here, in the wavy lines constituting the second conductive part, any one line may be a second wiring and the other lines may be second electrodes.

The touch panel may further include: a third conductive part formed in the same form as the wavy line on the transparent substrate, the third conductive part being disposed at one side of the conductive patterns such that the third conductive part is disposed in parallel with a first line of the wavy lines constituting the conductive patterns; and additional conductive patterns formed on the transparent substrate, the additional conductive patterns electrically connecting between the third conductive part and a first line of the wavy lines constituting the second conductive part.

The wavy lines constituting the conductive patterns and the third conductive part may be arranged at an equal interval on the transparent substrate.

Here, in the wavy lines constituting the first conductive part, the first line may be a first wiring and the other lines may be first electrodes; and the wavy lines constituting the second conductive part may be second electrodes and the third conductive part may be a second wiring. The transparent substrate may be divided into an active area and a non-active area, and the conductive patterns and the connecting patterns may be formed in the active area.

The conductive patterns and the connecting patterns may be integrally formed of the same material.

### BRIEF DESCRIPTION OF THE DRAWINGS

The above and other objects, features, and advantages of the present invention will be more clearly understood from the following detailed description taken in conjunction with the accompanying drawings, in which:

FIG. 1 is a plane view showing a transparent substrate of a touch panel according to a first preferred embodiment of the present invention;

FIG. 2 is a main plane view showing conductive patterns and connecting patterns of the touch panel according to the first preferred embodiment of the present invention;

FIG. 3 is a main plane view showing conductive patterns and connecting patterns of a touch panel according to a second preferred embodiment of the present invention;

FIG. 4 is an enlarged view of area A shown in FIG. 3; and

FIG. 5 is a main plane view showing conductive patterns and connecting patterns of a touch panel according to a third preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

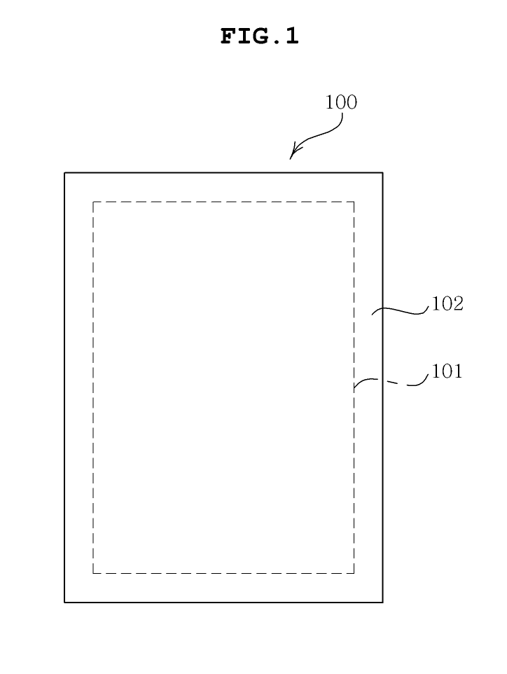

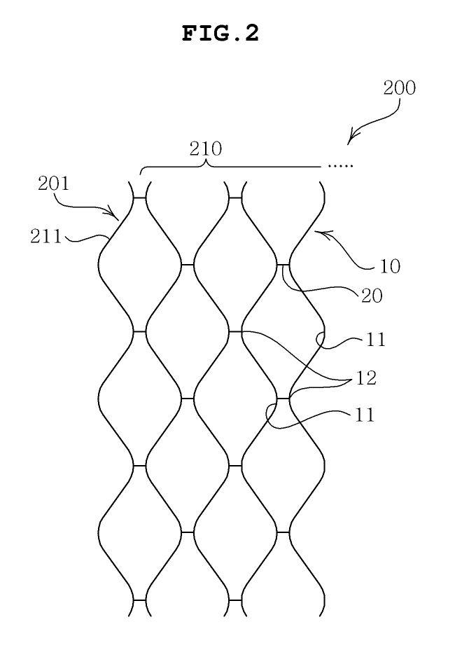

FIG. 1 is a plane view showing a transparent substrate of a touch panel according to a first preferred embodiment of the present invention; and FIG. 2 is a main plane view showing conductive patterns and connecting patterns of the touch panel according to the first preferred embodiment of the present invention.

Referring to FIGS. 1 and 2, a touch panel according to a first preferred embodiment of the present invention may include: a transparent substrate 100; conductive patterns 200 formed on the transparent substrate 100 such that wavy lines 10 spaced apart from each other and disposed in parallel with each other, each of the wavy lines 10 having a sine wave form where first peaks 11 and second peaks 12 alternately continue along a length direction; and connecting patterns 20 formed on the transparent substrate 100, each of the connecting patterns 20 electrically connecting between the wave lines 10.

The transparent substrate 100 serves to provide an area in which the conductive patterns 200 are to be formed. The transparent substrate 100 needs to have support force for supporting the conductive patterns 200 and transparency for allowing a user to recognize an image provided by an image display device.

In consideration of the foregoing support force and transparency, the transparent substrate 100 is preferably formed of polyethyleneterephthalate (PET), polycarbonate (PC), polymethylmethacrylate (PMMA), polyethylenenaphthalate (PEN), polyethersulfone (PES), cyclic olefin copolymer (COC), triacetylcellulose (TAC) film, polyvinyl alcohol (PVA) film, polyimide (PI) film, polystyrene (PS), biaxially oriented polystyrene (BOPS; containing K resin), glass or reinforced glass, and the like, but is not necessarily limited thereto.

Meanwhile, the transparent substrate 100 may be a window provided at the outermost side of the touch panel. In the case where the transparent substrate 100 is the window, since the conductive patterns 200 are formed directly on the window, processes of forming the electrodes on a separate transparent substrate 100 and then attaching the transparent substrate 100 to the window can be omitted and the overall thickness of the touch panel can be reduced.

The transparent substrate 100 may be divided into an active area 101 and a non-active area 102 disposed outside the edge of the active area 101, as shown in FIG. 1. The active area 101 is an area in which touching is implemented by a user, and also a screen area in which a motion scene of the touch panel is visibly recognized by the user. In addition, the non-active area 102 is an area that is covered by a bezel part (not shown) having black or white color and formed at the edge of the transparent substrate 100 or the window, to thereby not be exposed to the outside.

In the conductive patterns 200, some may be used as the wiring and the others may be used as the electrodes. Here, the electrodes serve to generate a signal when being touched by a user, to thereby allow the touched coordinate to be recognized by a controller (not shown). The signal generated from the electrodes is transmitted to the controller through the wirings. Specifically, the wirings are electrically connected with the electrodes and connected with the flexible circuit board (not shown) coupled to the transparent substrate 100, to thereby transmit the signal generated from the electrodes to the controller.

The conductive patterns 200 may account for a predetermined region in the active area 101 of one surface of the transparent substrate 100. The conductive patterns 200 are formed in a type of wavy lines 10 each having a sine wave where first peaks 11 and second peaks 12 alternately continue along the length direction. The wave lines 10 are spaced apart from each other and arranged in parallel with each other.

Here, as for the conductive pattern 200, a plurality of wavy lines 10 may be spaced apart from each other at an equal interval and arranged in parallel with each other. In addition, in the conductive patterns 200, the first peak 11 of any one of the neighboring wavy lines 10 may be opposite to the second peak 12 of the other of the neighboring wavy lines 10. Here, the distance between the first peak 11 of any one of the neighboring wavy lines 10 and the second peak 12 of the other of the neighboring wavy lines 10 may be the shortest interval between the neighboring wavy lines 10. As for the conductive patterns 200, the first peak 11 of any one of the neighboring wavy lines 10 and the second peak 12 of the other of the neighboring wavy lines 10 are formed to face each other, so that the second peak 12 of any one of the neighboring wavy lines 10 is positioned to face the first peak 11 of the other of the neighboring wavy lines 10 face each other.

The conductive patterns 200 are formed as described above, thereby forming a uniform pattern overall.

In the wavy lines 10 constituting the conductive pattern 200, some may be used as the wirings and the others may be used as the electrodes, and this will be described below.

Meanwhile, the connecting patterns 20 serve to electrically connect between the wavy lines 10 constituting the conductive patterns 200. The connecting patterns 20 may perform the foregoing function while being made in various structures. For example, the connecting pattern 20 is formed in a line shape as shown in FIG. 2, and has a structure where both ends of the connecting pattern 20 connects the first peak 11 and the second peak 12 forming the shortest interval. The wavy lines 10 constituting the conductive patterns 200 may be electrically connected by the connecting patterns 20. In addition, the connecting patterns 20 may be thoroughly formed between the first peak 11 and the second peak 12 making the shortest interval, as shown in FIG. 2, or although not shown, the connecting patterns 20 may be formed between the first peak 11 and the second peak 12 of only some of the wavy lines.

In the foregoing conductive pattern 200, some of the wavy lines 10 constituting the conductive patterns 200 may be used as the wirings. For example, a first line 201, which is disposed at the left end among the wavy lines 10 constituting the conductive patterns 200 may be used as a wiring 211. In addition, the other lines excluding the first line 201 may be used as the electrodes 210. Although not shown, the first line 201 may be formed such that an end thereof continues to the non-active area of the transparent substrate 100, and the end of the first line 201 may be a connection terminal connected to a flexible circuit board (not shown). In these conductive patterns 200, the touch signal sensed by the electrode 210 may be transmitted to the first line 201, which is electrically connected thereto by the connecting pattern 20, that is, the wiring 211, and subsequently may be transmitted to a flexible circuit board through the first line 201.

Meanwhile, the conductive patterns 200 and the connecting patterns 20 may be formed of a metal material having high electrical conductivity and easy processability. As the metal material, copper (Cu), aluminum (Al), gold (Au), silver (Ag), titanium (Ti), palladium (Pd), chrome (Cr), or a combination thereof may be used. The conductive patterns 200 and the connecting patterns 20 may be formed on the transparent substrate 100 by various methods such as a plating process, a depositing process, and the like. Here, the conductive patterns 200 and the connecting patterns 20 may be integrally formed.

As well, the conductive patterns 200 and the connecting patterns 20 may be formed of metallic silver formed by exposing/developing a silver salt emulsion layer in addition to the foregoing metal materials.

Hereinafter, a second preferred embodiment of the present invention will be described with reference to the accompanying drawings. However, the description overlapping the contents described in the first preferred embodiment will be omitted.

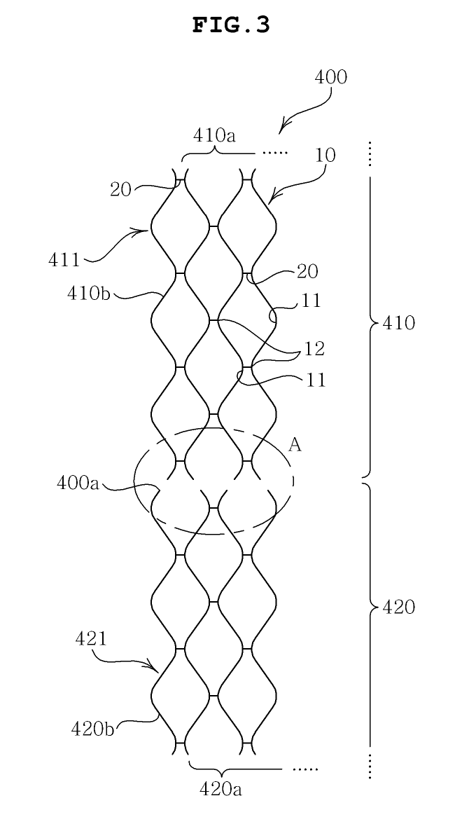

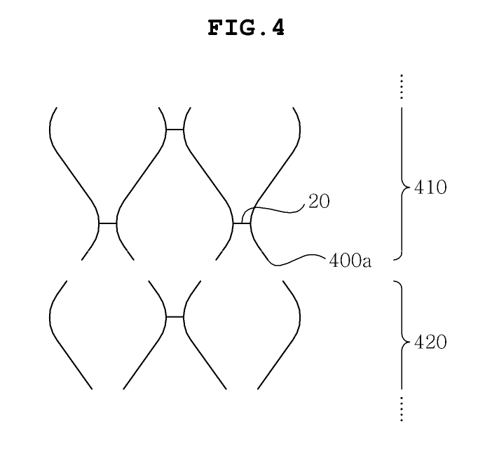

FIG. 3 is a main plane view showing conductive patterns and connecting patterns of a touch panel according to a second preferred embodiment of the present invention; and FIG. 4 is an enlarged view of area A shown in FIG. 3.

Referring to FIGS. 3 and 4, a touch panel according to a second preferred embodiment of the present invention may include: a transparent substrate 100 (see, FIG. 1); conductive patterns 400 formed on the transparent substrate 100 such that wavy lines 10 are spaced apart from each other and disposed in parallel with each other, each of the wavy lines 10 having a sine wave form where first peaks 11 and second peaks 12 alternately continue along a length direction thereof, and the conductive patterns being divided into a first conductive part 410 and a second conductive part 420 by forming a cut portion 400a in the wavy lines 10; and connecting patterns 400 formed on the transparent substrate 100, each of the connecting patterns 20 electrically connecting between the wave lines 10.

The wavy lines 10 constituting the conductive patterns 400 is the same as the wavy lines 10 described in the first preferred embodiment. In addition, the arrangement type of the wavy lines 10 constituting the conductive patterns 400 is the same as the arrangement type of the wavy lines 10 of the conductive patterns 200 described in the first preferred embodiment. In addition, as for the conductive patterns 400, each of the connecting patterns 20 is formed between the wavy lines 10, so that the wavy lines 10 can be electrically connected to each other.

Meanwhile, in the present preferred embodiment, the cut portion 400a is formed in the plurality of wavy lines 10 arranged in parallel with each other, so that the conductive patterns 400 is divided into the first conductive part 410 and the second conductive part 420. FIG. 3 shows an example where the cut portion 400a is formed in the plurality of wavy lines 10 along a horizontal direction, that is, a direction vertical to a length direction of the wavy line 10, to thereby arrange the first conductive part 410 and the second conductive part 420 in a vertical direction. Here, the cut portion 400a means a portion where the wavy line 10 is not connected but disconnected, as shown in FIG. 4. The wavy line 10 is insulated with the cut portion 400a taken as a boundary by forming the cut portion 400a disconnected as above.

Meanwhile, in the first conductive part 410, any one of the wavy lines 10 constituting the first conductive part 410 may be used as a wiring. In addition, the other wavy lines 10 may be used as electrodes. Also, in the second conductive part 420, any one of the wavy lines 10 constituting the second conductive part 420 may be used as a wiring and the other wavy lines may be used as electrodes.

For example, FIG. 3 shows a case where, in the wavy lines 10 constituting the first conductive part 410, the first line 411 is used as a first wiring 410b and the other lines are used as first electrodes 410a, and in the wavy lines 10 constituting the second conductive part 420, the first line 421 is used as a second wiring 420b and the other lines are used as second electrodes 420a. Here, each of the first line 411 of the first conductive part 410 and the first line 421 of the second conductive part 420 is one wavy line 10, but is electrically insulated from each other by forming the cutting portion 400a therein. The first line 411 of the first conductive part 410 and the first line 421 of the second conductive part 420 are formed oppositely to each other in a length direction thereof and may continue to the non-active area 102 of the transparent substrate 100.

Meanwhile, the present preferred embodiment exemplifies a case where the first lines 411 and 421 positioned at one sides of the first and second conductive parts 410 and 420 are used as the wirings 410b and 420b, but is not limited to this case. The present invention has the present preferred embodiment and various preferred embodiments. For example, the wavy line positioned at one side of any one of the first and second conductive parts 410 and 420 is used as a wiring and the wavy line positioned at the other side of the other of the first and second conductive parts 410 and 420 is used as a wiring.

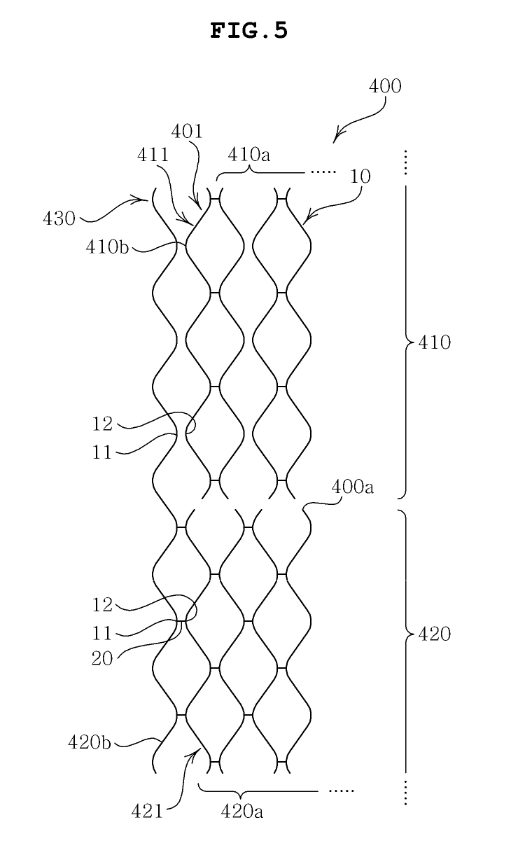

FIG. 5 is a main plane view showing conductive patterns and connecting patterns of a touch panel according to a third preferred embodiment of the present invention. The present preferred embodiment is not largely different from the second preferred embodiment, and only the differences therebetween will be described as follows.

The present preferred embodiment further includes a third conductive part 430 formed on the transparent substrate 100 (see, FIG. 1). The third conductive part 430 is composed of a wavy line having the same sine wave form as the foregoing wavy lines 10. In addition, the third conductive part 430 is formed at one side of the conductive patterns 400 such that the third conductive part 430 is disposed in parallel with the first line 401 of the wavy lines 10 constituting the conductive patterns 400. In addition, the third conductive part 430 may be spaced apart from the first line 401 of the conductive patterns 400 at an interval that is equal to an interval between the plurality of wavy lines 10 constituting the conductive patterns 400. Also, like the arrangement type of wavy lines 10 constituting the conductive patterns 400, the third conductive part 430 is formed such that the first peak 11 of the third conductive part 430 faces the second peak 12 of the first line 401 of the conductive patterns 400, and the distance therebetween has the shortest interval between the two lines.

Since the third conductive part 430 is formed as described above, the third conductive part 430 and the conductive patterns 400 form a uniform pattern overall.

Meanwhile, the third conductive part 430 may be electrically connected with the first line 421 of the second conductive part 420 of the conductive patterns 400. That is, the third conductive part 430 and the first line 421 of the second conductive part 420 may be electrically connected with each other by forming additional connecting patterns 20 having the same shape as the foregoing connecting patterns and connecting between the first peaks 11 of the third conductive part 430 and the second peaks 12 of the first line 421 of the second conductive part 420.

This third conductive part 430 may be the second wiring 420b electrically connected to the second conductive part 420 that is overall usable as the second electrodes 420a. In addition, the first line 411 of the first conductive part 410 may be used as the first wiring 410b and the other lines thereof may be used as the first electrodes 410a.

Meanwhile, the present invention is not limited to the foregoing preferred embodiment. The conductive patterns 400 may be divided into three or more electrode parts including the first electrodes 410a and the second electrodes 420a, by forming two or more rows of cutting portions 400a in the wavy lines 10. In addition, the wavy lines 10 adjacent to the respective electrodes may be used as wirings electrically connected to the respective electrodes 210 by being connected with the wavy lines 10 constituting the respective electrodes 210 by the connecting patterns 20.

As described above, according to the present invention, the conductive patterns that are usable as the wirings and electrodes are formed in the same wavy line 10, thereby forming an overall uniform pattern. Therefore, even though the wirings and the electrodes are disposed in the active area 101 of the transparent substrate 100, visibility of the touch panel is not deteriorated.

Due to this, according to the present invention, the non-active area 102 of the transparent substrate 100 can be reduced, and thus the entire size of the touch panel can be miniaturized or the screen area becomes wider as compared with the touch panels having the same area.

As set forth above, the electrodes and the wirings have an overall uniform pattern, by using some of the conductive patterns formed in a uniform pattern as the wirings and using the others thereof as the electrodes. Hence, according to the present invention, visibility of the touch panel can be excellent even though the wirings and the electrodes are disposed in the active area of the transparent substrate.

Further, due to the above advantages, the non-active area of the transparent substrate can be reduced, and thereby the width of the bezel part of the touch panel can be decreased. Therefore, the structure of the touch panel can be miniaturized or a screen area can be wider as compared with the touch panels having the same area.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A touch panel, comprising:
a transparent substrate;
conductive patterns formed on the transparent substrate such that wavy lines thereof are spaced apart from each other and arranged in parallel with each other, each of the wavy lines having a sine wave form where first peaks and second peaks alternately continue along a length direction thereof; and
connecting patterns formed on the transparent substrate, each of the connecting patterns electrically connecting between the wave lines.

2. The touch panel as set forth in claim 1, wherein in the conductive patterns, the first peaks of any one of neighboring wavy lines and the second peaks of the other of the neighboring wavy lines face each other while a distance between the neighboring wavy lines has the shortest interval.

3. The touch panel as set forth in claim 2, wherein the connecting pattern is formed in a line shape, both ends of the connecting pattern being connected to the first peak of any one of the neighboring wavy lines and the second peak of the other of the neighboring wavy lines.

4. The touch panel as set forth in claim 1, wherein in the wavy lines constituting the conductive patterns, any one line is a wiring and the other lines are electrodes.

5. The touch panel as set forth in claim 1, wherein the wavy lines are arranged at an equal interval on the transparent substrate.

6. The touch panel as set forth in claim 1, wherein the transparent substrate is divided into an active area and a non-active area, and the conductive patterns and the connecting patterns are formed in the active area.

7. The touch panel as set forth in claim 1, wherein the conductive patterns and the connecting patterns are integrally formed of the same material.

8. A touch panel, comprising:
a transparent substrate;
conductive patterns formed on the transparent substrate such that wavy lines thereof are spaced apart from each other and disposed in parallel with each other, each of the wavy lines having a sine wave form where first peaks and second peaks alternately continue along a length direction thereof, and the conductive patterns being divided into a first conductive part and a second conductive part by forming a cut portion in the wavy lines; and
connecting patterns formed on the transparent substrate, each of the connecting patterns electrically connecting between the wave lines.

9. The touch panel as set forth in claim 8, wherein in the conductive patterns, the first peaks of any one of neighboring wavy lines and the second peaks of the other of the neighboring wave lines face each other while a distance between the neighboring wavy lines has the shortest interval.

10. The touch panel as set forth in claim 8, wherein the connecting pattern is formed in a line shape, both ends of the connecting pattern being connected to the first peaks of any one of neighboring wavy lines and the second peaks of the other of the neighboring wavy lines.

11. The touch panel as set forth in claim 8, wherein the cutting portion is formed in the wavy lines along a direction orthogonal to the length direction of the wavy lines.

12. The touch panel as set forth in claim 8, wherein in the wavy lines constituting the first conductive part, any one line is a first wiring and the other lines are first electrodes.

13. The touch panel as set forth in claim 8, wherein in the wavy lines constituting the second conductive part, any one line is a second wiring and the other lines are second electrodes.

14. The touch panel as set forth in claim 8, further comprising:
a third conductive part formed in the same form as the wavy line on the transparent substrate, the third conductive part being disposed at one side of the conductive patterns such that the third conductive part is disposed in parallel with a first line of the wavy lines constituting the conductive patterns; and
additional conductive patterns formed on the transparent substrate, the additional conductive patterns electrically connecting between the third conductive part and a first line of the wavy lines constituting the second conductive part.

15. The touch panel as set forth in claim 14, wherein the wavy lines constituting the conductive patterns and the third conductive part are arranged at an equal interval on the transparent substrate.

16. The touch panel as set forth in claim 14, wherein in the wavy lines constituting the first conductive part, the first line is a first wiring and the other lines are first electrodes; and the wavy lines constituting the second conductive part are second electrodes and the third conductive part is a second wiring.

17. The touch panel as set forth in claim 8, wherein the transparent substrate is divided into an active area and a non-active area, and the conductive patterns and the connecting patterns are formed in the active area.

18. The touch panel as set forth in claim 8, wherein the conductive patterns and the connecting patterns are integrally formed of the same material.
